(19) United States
(12) Patent Application Publication
(10) Pub. No.: US 2023/0112891 A1
(43) Pub. Date: Apr. 13, 2023

(54) SEMICONDUCTOR PACKAGE AND METHOD OF FABRICATING THE SAME

(71) Applicant: SAMSUNG ELECTRONICS CO., LTD., Suwon-si (KR)

(72) Inventors: Jinyoung KIM, Suwon-si (KR); Kiseok KIM, Yongin-si (KR); Okseon YOON, Suwon-si (KR)

(21) Appl. No.: 17/852,614

(22) Filed: Jun. 29, 2022

(30) Foreign Application Priority Data
Oct. 12, 2021 (KR) 10-2021-0135300

(51) Int. Cl. H01L 23/498; H01L 23/31; H01L 23/538; H01L 25/10; C09K 11/06

(52) U.S. Cl. CPC H01L 23/49894; H01L 23/49822; H01L 23/3128; H01L 23/49811; H01L 23/5385; H01L 25/105; C09K 11/06; H01L 2224/16227; H01L 24/16

(57) ABSTRACT

Disclosed are semiconductor packages and their fabrication methods. The semiconductor package includes a redistribution substrate that includes an organic dielectric layer and a metal pattern in the organic dielectric layer, and a semiconductor chip on the redistribution substrate. The organic dielectric layer has a maximum absorbance equal to or greater than about 0.04 at a first wavelength range, and a fluorescence intensity equal to or greater than about 4×10³ at the first wavelength range. The first wavelength range is about 450 nm to about 650 nm.

### CROSS-REFERENCE TO RELATED APPLICATION

This U.S. nonprovisional application claims priority under 35 U.S.C. § 119 to Korean Patent Application No. 10-2021-0135300 filed on Oct. 12, 2021, in the Korean Intellectual Property Office, the disclosure of which is hereby incorporated by reference in its entirety.

### BACKGROUND

### 1. Field

Embodiments relate to a semiconductor package, and more particularly, to a semiconductor package including a redistribution substrate and a method of fabricating the same.

### 2. Description of the Related Art

A semiconductor package is provided to implement an integrated circuit chip for use in electronic products. A semiconductor package may be configured such that a semiconductor chip is mounted on a printed circuit board, and bonding wires or bumps are used to electrically connect the semiconductor chip to the printed circuit board. With the development of electronic industry, various researches have been conducted to improve reliability and durability of semiconductor packages.

### SUMMARY

According to an embodiment, a semiconductor package may include: a redistribution substrate that includes an organic dielectric layer and a metal pattern in the organic dielectric layer; and a semiconductor chip on the redistribution substrate. The organic dielectric layer may have a maximum absorbance equal to or greater than about 0.04 at a first wavelength range, and a fluorescence intensity equal to or greater than about 4×10³ at the first wavelength range. The first wavelength range may be about 450 nm to about 650 nm.

According to an embodiment, a semiconductor package may include: a redistribution substrate that includes a dielectric layer and a metal pattern in the dielectric layer; a plurality of solder balls on a bottom surface of the redistribution substrate; and a semiconductor chip on a top surface of the redistribution substrate. The dielectric layer may have a definite integral value equal to or greater than about 13 of an absorbance function at a first wavelength range, and a fluorescence intensity equal to or greater than about 4×10³ at the first wavelength range. The dielectric layer may satisfy at least one selected from a first fluorescence condition and a first absorbance condition. The first fluorescence condition may include that the fluorescence intensity is equal to or greater than about 1.0×10⁶. The first absorbance condition may include that a definite integral value is equal to or greater than about 40 of the absorbance function at the first wavelength range. The first wavelength range may be about 450 nm to about 650 nm.

According to an embodiment, a semiconductor package may include: a redistribution substrate that includes a dielectric layer and a redistribution pattern in the dielectric layer; a plurality of solder balls on a bottom surface of the redistribution substrate; a semiconductor chip on a top surface of the redistribution substrate; and a molding layer on the top surface of the redistribution substrate, the molding layer covering the semiconductor chip. The redistribution pattern may include a seed pattern and a metal pattern on the seed pattern. The dielectric layer may include a base resin, a cross-linking agent, an elastomer, a photo active compound, and a photosensitizer. The dielectric layer may have a maximum absorbance equal to or greater than about 0.04 at a first wavelength range, an integral intensity equal to or greater than about 13 at the first wavelength range, and a fluorescence intensity equal to or greater than about 4×10³ at the first wavelength range. The dielectric layer may satisfy at least one selected from a first fluorescence condition and a first absorbance condition. The first fluorescence condition may include that the fluorescence intensity is equal to or greater than about 1.0×10⁶. The first absorbance condition may include that the integral intensity is equal to or greater than about 40. The first wavelength range may be about 450 nm to about 650 nm.

According to an embodiment, a method of fabricating a semiconductor package may include: forming a first dielectric layer; forming a first redistribution pattern on the first dielectric layer; and inspecting the first redistribution pattern. The step of inspecting the first redistribution pattern may include: irradiating the first dielectric layer and the first redistribution pattern with visible light having a first wavelength range to analyze an image due to difference in absorbance between the first dielectric layer and the first redistribution pattern; and irradiating the first dielectric layer and the first redistribution pattern with light having a second wavelength to analyze an image due to difference in fluorescence properties between the first dielectric layer and the first redistribution pattern. The first wavelength range may be about 450 nm to about 650 nm.

### BRIEF DESCRIPTION OF THE DRAWINGS

Features will become apparent to those of skill in the art by describing in detail example embodiments with reference to the attached drawings in which:

FIG. 1A illustrates a cross-sectional view showing a semiconductor package according to some example embodiments.

FIG. 1B illustrates an enlarged view showing section I of FIG. 1A.

FIG. 2 illustrates a flow chart showing a redistribution substrate inspection according to some example embodiments.

FIGS. 3A to 3L illustrate cross-sectional views showing a method of fabricating a semiconductor package according to some example embodiments.

FIG. 4 illustrates a cross-sectional view showing a semiconductor package according to some example embodiments.

FIG. 5A illustrates a cross-sectional view showing a semiconductor package according to some example embodiments.

FIG. 5B illustrates an enlarged view showing section I of FIG. 5A.

FIG. 6A illustrates a cross-sectional view showing a semiconductor package according to some example embodiments.

FIG. 6B illustrates an enlarged cross-sectional view showing section II of FIG. 6A.

FIG. 6C illustrates a cross-sectional view showing a semiconductor package according to some example embodiments.

FIG. 7 illustrates a cross-sectional view showing a semiconductor package according to some example embodiments.

FIG. 8A illustrates a graph showing an evaluation result of absorbance of Experimental Examples 1 to 5.

FIG. 8B illustrates a graph showing an evaluation result of fluorescence intensity of Experimental Examples 1 to 5 when irradiating light whose wavelength is about 405 nm.

FIG. 8C illustrates a graph showing an evaluation result of fluorescence intensity of Experimental Examples 1 to 5 when irradiating light whose wavelength is about 480 nm.

### DETAILED DESCRIPTION

The following will now describe a semiconductor package and its fabrication method according to example embodiments.

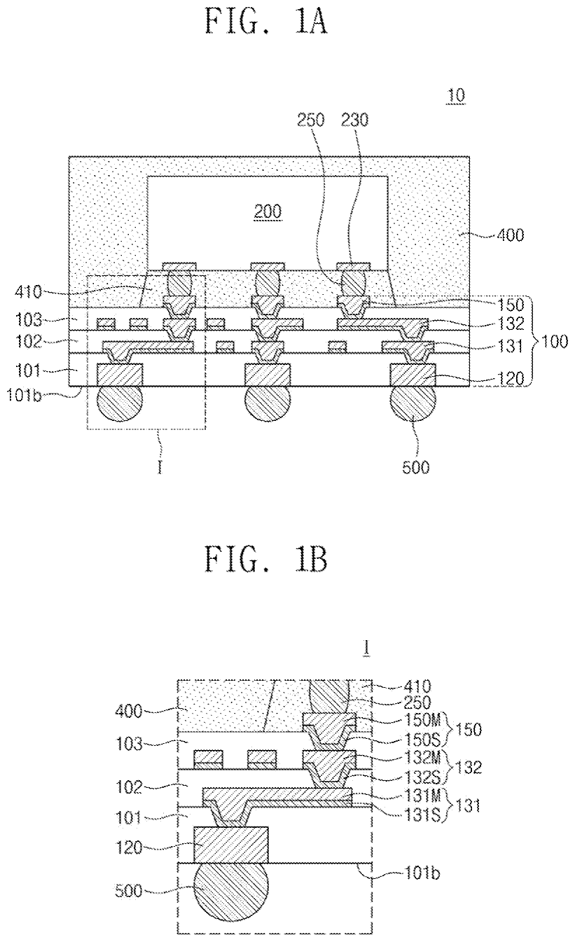

FIG. 1A illustrates a cross-sectional view showing a semiconductor package according to some example embodiments. FIG. 1B illustrates an enlarged view showing section I of FIG. 1A.

Referring to FIGS. 1A and 1B, a semiconductor package 10 may include a first redistribution substrate 100, solder balls 500, a semiconductor chip 200, and a molding layer 400.

The first redistribution substrate 100 may include a dielectric layer, under-bump patterns 120, first redistribution patterns 131, second redistribution patterns 132, and first redistribution pads 150.

The dielectric layer may include a first dielectric layer 101, a second dielectric layer 102, and a third dielectric layer 103 that are stacked. The first dielectric layer 101, the second dielectric layer 102, and the third dielectric layer 103 may be organic dielectric layers. The first dielectric layer 101, the second dielectric layer 102, and the third dielectric layer 103 may include, e.g., a photo-imageable dielectric (PID).

Each of the first dielectric layer 101, the second dielectric layer 102, and the third dielectric layer 103 may absorb light having a first wavelength range. For example, each of the first dielectric layer 101, the second dielectric layer 102, and the third dielectric layer 103 may have an absorbance equal to or greater than about 0.04 with respect to light having the first wavelength range. The absorbance may be a maximum absorbance. Each of the first dielectric layer 101, the second dielectric layer 102, and the third dielectric layer 103 may have an integral intensity equal to or greater than about 13 at the absorbance of the first wavelength range. The integral intensity may be a definite integral value of an absorbance function at the first wavelength range. The integral intensity may be an area of an absorbance function at the first wavelength range. The light of the first wavelength range may be light having a visible wavelength. For example, the first wavelength range may be from about 450 nm to about 650 nm. In this description, the absorbance may be measured under the condition of thickness of about 3 μm to about 15 μm.

Each of the first dielectric layer 101, the second dielectric layer 102, and the third dielectric layer 103 may further satisfy a first absorbance condition. The first absorbance condition may include having an absorbance equal to or greater than about 0.5 with respect to light having the first wavelength range. The first absorbance condition may include having an integral intensity equal to or greater than about 40 at the absorbance of the first wavelength range.

The first dielectric layer 101, the second dielectric layer 102, and the third dielectric layer 103 may have fluorescence properties with respect to incident light having a second wavelength. For example, when light having the second wavelength is irradiated, light having the first wavelength range may be emitted from the first dielectric layer 101, the second dielectric layer 102, and the third dielectric layer 103. The second wavelength may be an excitation wavelength. Each of the first dielectric layer 101, the second dielectric layer 102, and the third dielectric layer 103 may have a fluorescence intensity equal to or greater than about 4×10³ at an emission wavelength of the first wavelength range. Unless otherwise specified in this description, the fluorescence intensity may be measured under the condition of thickness of about 3 μm to about 15 μm.

The second wavelength may be less than the first wavelength range. The second wavelength may be, e.g., about 400 nm to about 410 nm.

Alternatively, the first wavelength range may include the second wavelength. For example, the second wavelength may be, e.g., about 475 nm to about 480 nm. In this case, a fluorescence emission wavelength of the first, second, and third dielectric layers 101, 102, and 103 may be greater than the second wavelength. The first wavelength range may include the fluorescence emission wavelength of the first, second, and third dielectric layers 101, 102, and 103. A range of the second wavelength may be variously changed.

Each of the first dielectric layer 101, the second dielectric layer 102, and the third dielectric layer 103 may further satisfy a first fluorescence condition. The first fluorescence condition may include having a fluorescence intensity equal to or greater than about 1.0×10⁶ at an emission wavelength of the first wavelength range.

The first dielectric layer 101, the second dielectric layer 102, and the third dielectric layer 103 may satisfy at least one selected from the first absorbance condition and the first fluorescence condition.

Each of the first dielectric layer 101, the second dielectric layer 102, and the third dielectric layer 103 may include a photo-imageable dielectric (PID) composition. The photo-imageable dielectric composition may include a base resin, a cross-linking agent, an elastomer, and a photo active compound (PAC).

The base resin may include one or more of polyhydroxystyrene (PHS), polybenzoxazole (PBO), polyimide (PI), novolac, benzocyclobutene (BCB), polyamide resin, phenolic resin, a derivative thereof, etc.

The cross-linking agent may include one or more of a methylol melamine compound, a compound having an epoxy functional group, a compound having an alkoxy functional group, a combination thereof, etc. The methylol melamine compound may include, e.g., one or more of hexamethylol melamine and hexabutanol melamine. The compound having an epoxy functional group may include one or more of 1,4-bis(methoxymethyl)benzene, 1,3-bis(methoxymethyl)benzene, 4,4′-bis(methoxymethyl)biphenyl, 3,4′-bis(methoxymethyl)biphenyl, 3,3′-bis(methoxymethyl)biphenyl, 2,6-naphthalene naphthalenedicarboxylic acid methyl, and 4,4′-methylenebis(2,6-methoxymethyl phenol). The compound having an epoxy functional group may include one or more of ethylene glycol diglycidyl ether, bisphenol A diglycidyl ether, isocyanuric acid triglycidyl, bisphenol A epoxy resin, bisphenol F epoxy resin, naphthalene epoxy resin, biphenyl epoxy resin, and phenol novolac epoxy resin.

The elastomer may include a first aromatic ring compound. The elastomer may include one or more of a phenolic compound, a melamine compound, an imide compound, a derivative thereof, etc.

The photo active compound may include one or more of diazonaphthoquinone and its derivative. The photo active compound may further include an onium compound such triaryl sulfonium salt as sulfonium borate. In this case, it may be possible to increase sensitivity of a layer fabricated by using the photo-imageable dielectric composition. Because the photo-imageable dielectric composition includes the photo active compound, the photo-imageable dielectric composition may have reactivity with respect to light in an exposure process.

The photo-imageable dielectric composition may further include a photosensitizer. The photosensitizer may include a second aromatic ring compound. The second aromatic ring compound may be different from the first aromatic ring compound. For example, the photosensitizer may include a melamine-based material. When the elastomer includes a melamine compound, the melamine compound of the elastomer may include a material different from the melamine-based material of the photosensitizer. For example, the melamine compound of the elastomer may have a chemical structure and/or a function group different from those of the melamine-based material of the photosensitizer. The photosensitizer may include a fluorescent material. Melamine may react with a solvent such as methanol, thereby forming a melamine methyl structure. The melamine methanol structure may have intramolecular charge transfer properties. The intramolecular charge transfer may cause the photosensitizer to exhibit fluorescent properties.

Alternatively, the photo-imageable dielectric composition may include no photosensitizer. In this case, one or both of the cross-linking agent and the elastomer may serve as a fluorescent material. For example, one or both of the cross-linking agent and the elastomer may have a backbone that exhibits fluorescent properties.

The photosensitizer may act as an electron donor. The photosensitizer may be an additive.

The first dielectric layer 101, the second dielectric layer 102, and the third dielectric layer 103 may exhibit fluorescence properties. The first dielectric layer 101, the second dielectric layer 102, and the third dielectric layer 103 may be manufactured by curing the photo-imageable dielectric composition. Therefore, the first, second, and third dielectric layers 101, 102, and 103 may be in a cured state.

The photo-imageable dielectric composition may further include a silane coupling agent. The silane coupling agent may have adhesive properties.

The photo-imageable dielectric composition may further include an antioxidant. The antioxidant may include at least one selected from a phenolic antioxidant, a phosphorus-containing antioxidant, and a thioether group-containing antioxidant.

The photo-imageable dielectric composition may have a viscosity of about 20 cP to about 8,000 cP.

The first dielectric layer 101, the second dielectric layer 102, and the third dielectric layer 103 may include the same photo-imageable dielectric composition. An indistinct interface may be provided between the first dielectric layer 101 and the second dielectric layer 102. An indistinct interface may be provided between the second dielectric layer 102 and the third dielectric layer 103.

Each of the first, second, and third dielectric layers 101, 102, and 103 may have a thickness of about 3 μm to about 15 μm. For example, each of the first, second, and third dielectric layers 101, 102, and 103 may have a thickness of about 3 μm to about 8 μm.

The under-bump patterns 120 may be provided in the first dielectric layer 101. The under-bump patterns 120 may have their bottom surface that are not covered with the first dielectric layer 101. The under-bump patterns 120 may serve as pads for the solder balls 500. The under-bump patterns 120 may be laterally spaced apart and electrically insulated from each other. The phrase “two components are laterally spaced apart from each other” may mean “two components are horizontally spaced apart from each other.” The term “horizontally” may mean “parallel to a bottom surface of the first redistribution substrate 100.” The bottom surface of the first redistribution substrate 100 may include a bottom surface 101b of the first dielectric layer 101 and the bottom surfaces of the under-bump patterns 120. The under-bump patterns 120 may include a metallic material, such as copper.

The first redistribution patterns 131 may be provided in and on the first dielectric layer 101. The first redistribution patterns 131 may be provided on and electrically connected to the under-bump patterns 120. The expression “two components are electrically connected to each other” may include the meaning that “two components are electrically directly connected to each other or indirectly connected to each other through other component(s).” The second dielectric layer 102 may be disposed on the first dielectric layer 101 and the first redistribution patterns 131, thereby covering top surfaces of the first redistribution patterns 131.

The second redistribution pattern 132 may be disposed on and electrically connected to the first redistribution pattern 131. The second redistribution patterns 132 may be provided in and on the second dielectric layer 102. The third dielectric layer 103 may be provided on the second dielectric layer 102 and top surfaces of the second redistribution patterns 132, thereby covering the top surfaces of the second redistribution patterns 132.

The first redistribution pads 150 may be disposed on and coupled to the second redistribution patterns 132. The first redistribution pads 150 may be laterally spaced apart from each other. The first redistribution pads 150 may be coupled to corresponding under-bump patterns 120 through the second redistribution patterns 132 and the first redistribution patterns 131. As the first and second redistribution patterns 131 and 132 are provided, at least one first redistribution pad 150 may not be vertically aligned with the under-bump pattern 120 electrically connected to the at least one first redistribution pad 150. Accordingly, it may be possible to freely design arrangement of the first redistribution pads 150.

The following will describe in detail the first redistribution patterns 131, the second redistribution patterns 132, and the first redistribution pads 150.

Referring to FIG. 1B, each of the first redistribution patterns 131 may include a first seed pattern 131S and a first metal pattern 131M. The first metal pattern 131M may include a first via part and a first wire part. The first via part may be provided in the first dielectric layer 101. The first wire part may be provided on the first via part, and the first wire part and the first via part may be connected to each other without an interface therebetween. The first wire part may extend onto a top surface of the first dielectric layer 101. In this description, the component “via” may be an element for vertical connection, and the component “wire” may be an element for horizontal connection. The term “vertical/perpendicular” may mean “vertical/perpendicular to the bottom surface of the first redistribution substrate 100.” The first metal pattern 131M may include metal, such as copper. The first seed pattern 131S may be interposed between the under-bump pattern 120 and the first metal pattern 131M, and between the first dielectric layer 101 and the first metal pattern 131M. The first seed pattern 131S may include a conductive seed material. The conductive seed material may include, e.g., one or more of copper, titanium, an alloy thereof, etc. The first seed pattern 131S may serve as a barrier layer to prevent diffusion of materials included in the first metal pattern 131M.

Each of the second redistribution patterns 132 may include a second seed pattern 132S and a second metal pattern 132M. The second metal pattern 132M may include a second via part and a second wire part. The second via part may be provided in the second dielectric layer 102. The second wire part may be provided on the second via part, and the second wire part and the second via part may be connected to each other without an interface therebetween. The second wire part may extend onto a top surface of the second dielectric layer 102. The second metal pattern 132M may include metal, such as copper. The second seed pattern 132S may be interposed between a corresponding first redistribution pattern 131 and the second metal pattern 132M, and between the second dielectric layer 102 and the second metal pattern 132M. The second seed pattern 132S may include a different material from that of the second metal pattern 132M. The second seed pattern 132S may include a conductive seed material. The second seed pattern 132S may serve as a barrier layer. The phrase “electrically connected to the first redistribution substrate 100” may include the meaning that “coupled to at least one selected from the first and second redistribution patterns 131 and 132.”

Each of the first redistribution pads 150 may include a seed pad 150S and a metal pad 150M. The metal pad 150M may have a lower portion provided in the second dielectric layer 102. The lower portion of the metal pad 150M may extend onto the top surface of the second dielectric layer 102. The metal pad 150M may include metal, such as copper. The seed pad 150S may be interposed between a corresponding second redistribution pattern 132 and the metal pad 150M and between the third dielectric layer 103 and the metal pad 150M. The seed pad 150S may include a different material from that of the metal pad 150M. The seed pad 150S may include a conductive seed material. The seed pad 150S may serve as a barrier layer.

Differently from that shown, third redistribution patterns may further be interposed between the second redistribution patterns 132 and the first redistribution pads 150. Alternatively, the second redistribution patterns 132 may be omitted, and the first redistribution pads 150 may be directly coupled to the first redistribution patterns 131.

Referring back to FIG. 1A, the solder balls 500 may be provided on the bottom surface of the first redistribution substrate 100. For example, the solder balls 500 may be correspondingly disposed on the bottom surfaces of the under-bump patterns 120, thereby being coupled to corresponding under-bump patterns 120. The solder balls 500 may be electrically connected through the under-bump patterns 120 to the first and second redistribution patterns 131 and 132. The solder balls 500 may include a solder material. The solder material may include, e.g., tin, bismuth, lead, silver, an alloy thereof, etc.

The semiconductor chip 200 may be mounted on a top surface of the first redistribution substrate 100. When viewed in plan, the semiconductor chip 200 may be disposed on a central region of the first redistribution substrate 100. The semiconductor chip 200 may be one of a logic chip, a buffer chip, and a memory chip.

The semiconductor chip 200 may have a top surface and a bottom surface that are opposite to each other. The bottom surface of the semiconductor chip 200 may be an active surface directed toward the first redistribution substrate 100. The top surface of the semiconductor chip 200 may be an inactive surface. For example, the semiconductor chip 200 may include a semiconductor substrate, integrated circuits (not shown), and chip pads 230. The semiconductor substrate may include one or more of silicon, germanium, and silicon-germanium. The integrated circuits may be adjacent to the bottom surface of the semiconductor chip 200. The chip pads 230 may be coupled to the integrated circuits. The phrase “a certain component is electrically connected to the semiconductor chip 200” may mean that “a certain component is electrically connected through the chip pads 230 to the integrated circuits of the semiconductor chip 200.”

The semiconductor package 10 may further include bumps 250. The bumps 250 may be interposed between the first redistribution substrate 100 and the semiconductor chip 200. For example, the bumps 250 may be provided between and coupled to the first redistribution pads 150 and the chip pads 230. Therefore, the semiconductor chip 200 may be coupled through the bumps 250 to the first redistribution substrate 100. The bumps 250 may include solder balls. The bumps 250 may include a solder material. The bumps 250 may further include pillar patterns, and the pillar patterns may include metal, such as copper.

The semiconductor package 10 may further include an underfill layer 410. The underfill layer 410 may be provided in a gap between the first redistribution substrate 100 and the semiconductor chip 200, thereby covering sidewalls of the bumps 250. The underfill layer 410 may include a dielectric polymer, such as an epoxy polymer.

The molding layer 400 may be provided on the top surface of the first redistribution substrate 100 to cover the semiconductor chip 200. The molding layer 400 may include a dielectric polymer, such as an epoxy polymer. The molding layer 400 may include a different material from that of the underfill layer 410.

The following will now discuss a method of fabricating a semiconductor package according to some example embodiments.

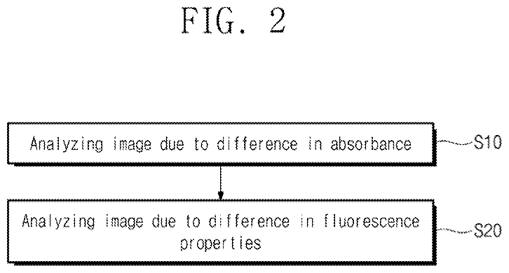

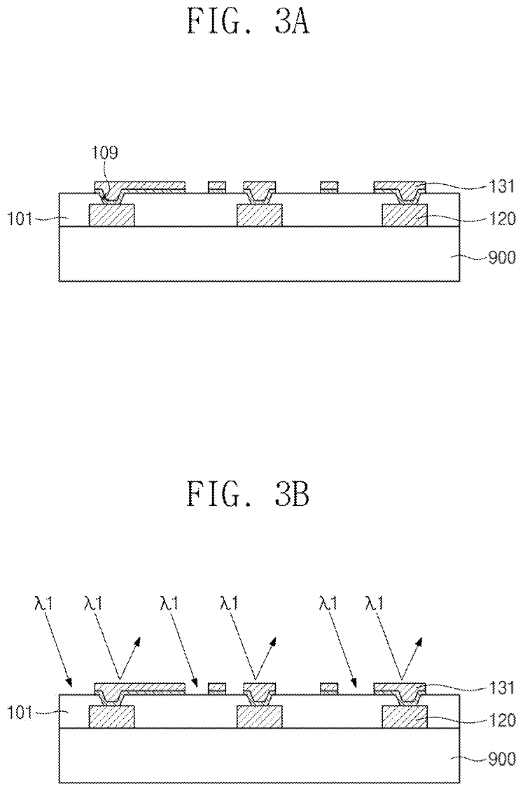

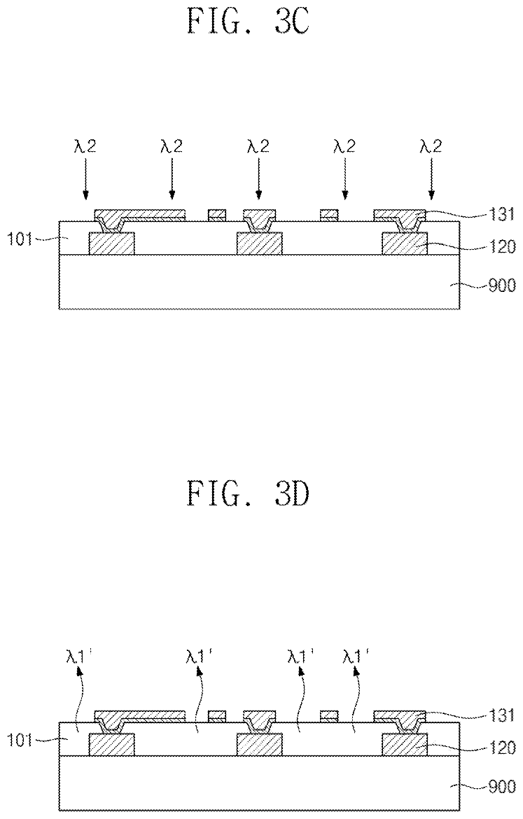

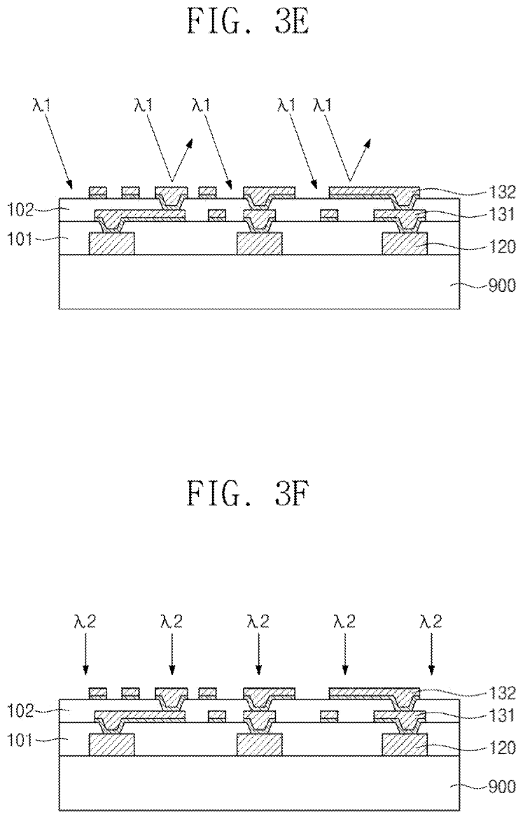

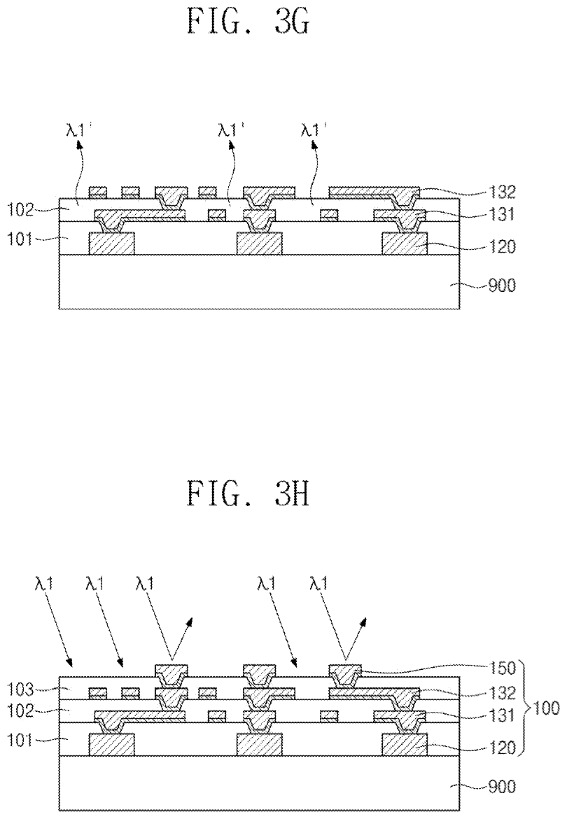

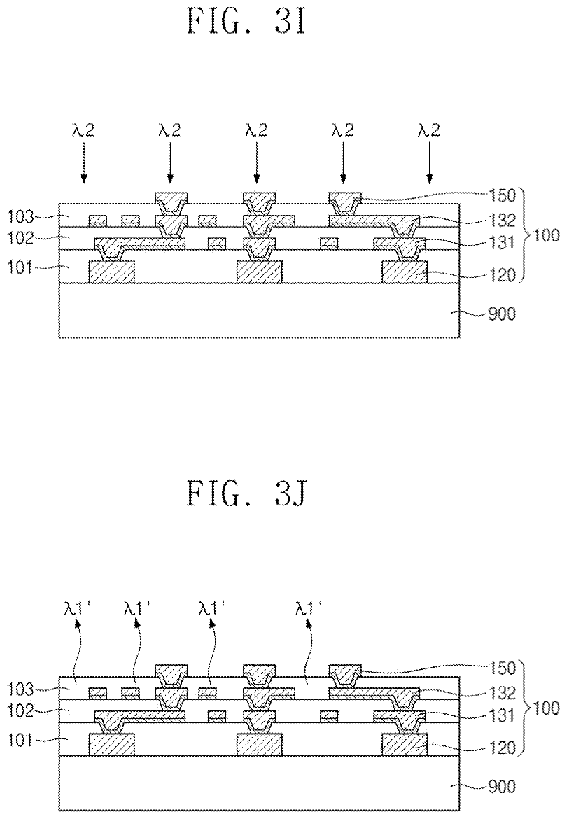

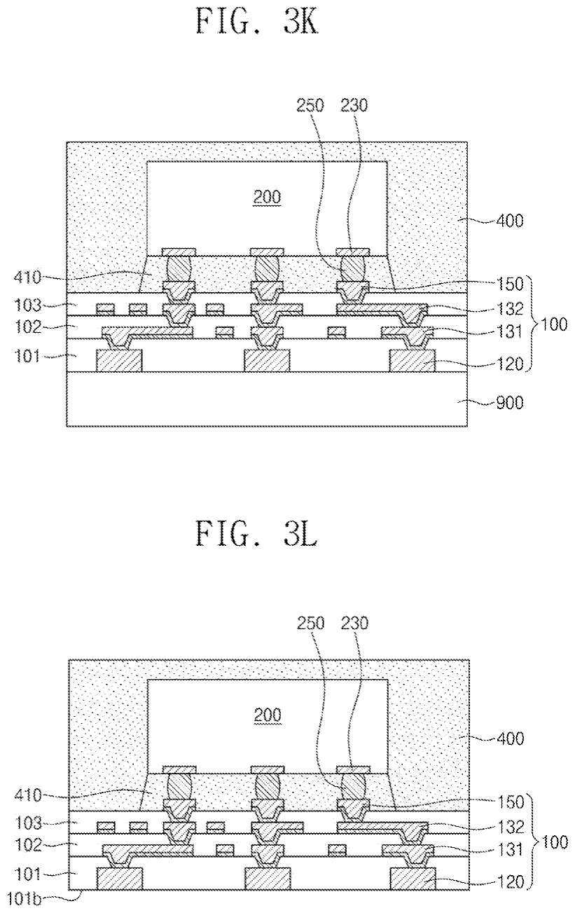

FIG. 2 illustrates a flow chart showing a redistribution substrate inspection according to some example embodiments. FIGS. 3A to 3L illustrate cross-sectional views showing a method of fabricating a semiconductor package according to some example embodiments.

Referring to FIG. 2, a redistribution substrate inspection may include an absorbance inspection and a fluorescence inspection. The absorbance inspection may include irradiating light having a first wavelength range, and analyzing an image due to difference in absorbance at the first wavelength range (S10). The fluorescence inspection may include irradiating light having a second wavelength to analyze an image due to difference in fluorescence properties at the first wavelength range (S20).

The first wavelength range may be about 450 nm to about 650 nm. The second wavelength may be less than the first wavelength range. For example, the second wavelength may be about 400 nm to about 410 nm.

According to some example embodiments, the fluorescence image analysis step S20 and the absorbance image analysis step S10 may be performed at the same first wavelength range. Therefore, the same spectral measurement device may be used to perform the absorbance image analysis step S10 and the fluorescence image analysis step S20. Accordingly, it may be possible to effectively and simply perform an inspection process on the first redistribution patterns 131.

According to some example embodiments, the absorbance image analysis step S10 may be performed before or after the fluorescence image analysis step S20. For example, the absorbance inspection may be executed before or after the fluorescence inspection. The absorbance inspection will be first discussed below in the interest of convenience.

Referring to FIG. 3A, under-bump patterns 120, a first dielectric layer 101, and first redistribution patterns 131 may be formed on a carrier substrate 900. According to some example embodiments, an electroplating process may be performed to form the under-bump patterns 120 on the carrier substrate 900. An inspection process may further be performed on the under-bump patterns 120. For example, the under-bump patterns 120 may be irradiated with light having a first wavelength range. The first dielectric layer 101 and the under-bump pattern 120 may be different in terms of absorbance to the light having a first wavelength range. For example, the absorbance of the first dielectric layer 101 with respect to light having the first wavelength range may be greater than the absorbance of the under-bump patterns 120 with respect to light having the first wavelength range. The under-bump patterns 120 may reflect light having the first wavelength range. The first dielectric layer 101 may absorb light having the first wavelength range. It may be possible to obtain information about arrangement and shape of the under-bump patterns 120 by analyzing an image due to difference in absorbance with respect to light having the first wavelength range between the first dielectric layer 101 and the under-bump patterns 120. The analysis of the image due to the absorbance difference may include analyzing contrast due to difference in absorbance between the first dielectric layer 101 and the under-bump patterns 120.

The first dielectric layer 101 may be formed on the carrier substrate 900 to cover sidewalls and top surfaces of the under-bump patterns 120. According to some example embodiments, the first dielectric layer 101 may be formed by performing a coating process that uses a photo-imageable dielectric composition. After the coating process, a free-bake process may further be performed on the first dielectric layer 101. The free-bake process may include performing an annealing process for about 30 seconds to about 30 minutes at a temperature of about 90° C. to about 130° C. The photo-imageable dielectric composition may include the base resin, the cross-linking agent, the elastomer, the photo active compound, and the photosensitizer, which are discussed in the example of FIGS. 1A to 1B. The first dielectric layer 101 may undergo exposure and development processes to form first openings 109. As the photo-imageable dielectric composition includes the photo active compound, the first dielectric layer 101 may be patterned by the exposure and development processes. The first openings 109 may expose the under-bump patterns 120. Afterwards, the first dielectric layer 101 may be cured. The curing process may be performed after the patterning process. The curing process may be a post-bake process. The curing process may include performing an annealing process for about 30 minutes to about 10 hours at a temperature of about 150° C. to about 350° C.

First redistribution patterns 131 may be formed in the first openings 109 and on a top surface of the first dielectric layer 101. The formation of the first redistribution patterns 131 may include performing a deposition process and an electroplating process. The first redistribution patterns 131 may expose at least a portion of the top surface of the first dielectric layer 101.

The following description will focus on examples of the redistribution substrate inspection with additional reference to FIGS. 3B to 3J.

Referring to FIGS. 2, 3B, 3C, and 3D, an inspection process may be performed on the first redistribution patterns 131. The inspection process of the first redistribution patterns 131 may include an absorbance inspection and a fluorescence inspection.

Referring to FIGS. 2 and 3B, the absorbance inspection may be performed on the first redistribution patterns 131 and the first dielectric layer 101. The absorbance inspection may include irradiating a light λ1 having the first wavelength range, and analyzing an image due to difference in absorbance at the first wavelength range (S10). The first dielectric layer 101 and the first redistribution pattern 131 may be different in terms of absorbance with respect to the light λ1 having the first wavelength range. For example, the absorbance of the first dielectric layer 101 with respect to light λ1 having the first wavelength range may be greater than the absorbance of the first redistribution patterns 131 with respect to light λ1 having the first wavelength range. The first redistribution patterns 131 may include metal and may reflect the light λ1 having the first wavelength range. The first dielectric layer 101 may absorb the light λ1 having the first wavelength range. It may be possible to obtain information about arrangement and shape of the first redistribution patterns 131 by analyzing an image due to difference in absorbance with respect to the light λ1 having the first wavelength range between the first dielectric layer 101 and the first redistribution patterns 131. The analysis of the image due to the absorbance difference may include analyzing contrast due to difference in absorbance between the first dielectric layer 101 and the first redistribution patterns 131. Therefore, defects of the first redistribution patterns 131 may be evaluated from the analyzed result. For example, the analyzed result may be used to evaluate whether the first redistribution patterns 131 are formed on desired positions. In addition, the analyzed result may be used to determine pass or fail of electrical connection of the first redistribution patterns 131. The fail of electrical connection may include a high likelihood of the occurrence of a short-circuit.

When the first dielectric layer 101 has an absorbance less than about 0.04 and an integral intensity less than about 13, the light λ1 having the first wavelength range may pass through the first dielectric layer 101. The light λ1 that has passed may be reflected from the under-bump patterns 120. In this case, noise may occur on information about arrangement and electrical connection of the first redistribution patterns 131. According to some example embodiments, the first dielectric layer 101 may have an absorbance equal to or greater than about 0.04 at the light λ1 having the first wavelength range, and an integral intensity equal to or greater than about 13 at the first wavelength range. Thus, the occurrence of noise may be reduced or prevented.

The first dielectric layer 101 may further satisfy the first absorbance condition discussed in FIG. 1A. For example, the first dielectric layer 101 may have an absorbance equal to or greater than about 0.5 at the light λ1 having the first wavelength range, and an integral intensity equal to or greater than about 40 at the first wavelength range. In this case, it may be possible to increase reliability and accuracy of results of analyzing the image due to difference in absorbance.

Referring to FIGS. 2, 3C, and 3D, the fluorescence inspection may be performed on the first redistribution patterns 131 and the first dielectric layer 101. The fluorescence inspection may include irradiating a light λ2 having a second wavelength, and then analyzing an image due to difference in fluorescence properties at the first wavelength range (S20).

As shown in FIG. 3C, the light λ2 having the second wavelength may be irradiated to the first redistribution patterns 131 and the first dielectric layer 101. The second wavelength may correspond to an excitation wavelength of the first dielectric layer 101. For example, the second wavelength may be less than the first wavelength range. For example, the second wavelength may range from about 400 nm to about 410 nm. For another example, the second wavelength may range from about 475 nm to about 485 nm.

As shown in FIG. 3D, the first dielectric layer 101 may absorb the light λ2 having the second wavelength, and may emit a light λ1′ having a first wavelength range. The light λ1′ having the first wavelength range may be fluorescently emitted light. The first wavelength range may be substantially the same as the first wavelength discussed in the examples of FIGS. 1A and 3B. Because the first redistribution patterns 131 have no fluorescence properties, no light may be emitted from the first redistribution patterns 131. It may be possible to analyze the image due to difference in fluorescence properties between the first dielectric layer 101 and the first redistribution patterns 131. The analysis of the image due to the fluorescence difference may include analyzing contrast due to difference in fluorescence properties between the first dielectric layer 101 and the first redistribution patterns 131. Data about shapes of the first redistribution patterns 131 may be obtained from analyzed results. For example, it may be possible to obtain data about the formation of undesired protrusions or recessions of the first redistribution patterns 131. In addition, it may be possible to obtain data about whether residues of the first redistribution patterns 131 remain on the first dielectric layer 101. The data may be analyzed to evaluate durability and reliability of the first redistribution patterns 131.

The data discussed above may be difficult to obtain when the first dielectric layer 101 has a fluorescence intensity less than about 4×10³ at the first wavelength range. According to some example embodiments, because the first dielectric layer 101 has a fluorescence intensity equal to or greater than about 4×10³ at an emission wavelength of the first wavelength range, it may be possible to increase reliability of analyzing the image due to difference in fluorescence properties.

The first dielectric layer 101 may further satisfy the first fluorescence condition discussed in FIG. 1A. For example, the first dielectric layer 101 may have an integral intensity equal to or greater than about 40 at the absorbance of the first wavelength range. In this case, the fluorescence inspection may increase in reliability.

Referring to FIG. 3E, a second dielectric layer 102 may be formed on and may cover the first dielectric layer 101 and the first redistribution patterns 131. The second dielectric layer 102 may be formed by substantially the same method as that used for forming the first dielectric layer 101 of FIG. 3A. The second dielectric layer 102 may be cured.

Second redistribution patterns 132 may be formed in the second dielectric layer 102 and on a top surface of the second dielectric layer 102. The second redistribution patterns 132 may be coupled to the first redistribution patterns 131. The formation of the second redistribution patterns 132 may include performing a deposition process and an electroplating process. The second redistribution patterns 132 may expose at least a portion of the top surface of the second dielectric layer 102.

An inspection process may be performed on the second redistribution patterns 132. The inspection process of the second redistribution patterns 132 may include an absorbance inspection and a fluorescence inspection. The absorbance inspection may include irradiating the light λ1 having the first wavelength range and analyzing an image due to difference in absorbance at the first wavelength range (S10). The absorbance inspection may be performed by the same method as that discussed in the example of the absorbance inspection of FIG. 3B. The second dielectric layer 102 and the second redistribution pattern 132 may be different in terms of absorbance with respect to the light λ1 having the first wavelength range. The second redistribution patterns 132 may reflect the light λ1 having the first wavelength range. The second dielectric layer 102 may absorb the light λ1 having the first wavelength range. It may be possible to obtain information about arrangement and shape of the second redistribution patterns 132 by analyzing an image due to difference in absorbance with respect to the light λ1 having the first wavelength range between the second dielectric layer 102 and the second redistribution patterns 132. The analysis of the image due to the absorbance difference may include analyzing contrast due to difference in absorbance between the second dielectric layer 102 and the second redistribution patterns 132. Information about arrangement and electrical connection of the second redistribution patterns 132 may be obtained from analyzed results. The information may be used to evaluate whether the second redistribution patterns 132 are defective.

When the second dielectric layer 102 has an absorbance less than about 0.04 and an integral intensity less than about 13, the light λ1 having the first wavelength range may pass through the second dielectric layer 102, and the light λ1 that has passed through may be reflected from the first redistribution patterns 131 to produce noise. According to some example embodiments, the second dielectric layer 102 may have an absorbance equal to or greater than about 0.04 at the light λ1 having the first wavelength range, and an integral intensity equal to or greater than about 13 at the first wavelength range. Thus, the occurrence of noise may be reduced or prevented.

The second dielectric layer 102 may further satisfy the first absorbance condition discussed in FIG. 1A. For example, the second dielectric layer 102 may have an absorbance equal to or greater than about 0.5 at the light λ1 having the first wavelength range, and an integral intensity equal to or greater than about 40 at the first wavelength range. In this case, it may be possible to increase reliability and accuracy of results of analyzing the image due to difference in absorbance.

Referring to FIGS. 2, 3F, and 3G, the fluorescence inspection may be performed on the second redistribution patterns 132. The fluorescence inspection of the second redistribution patterns 132 may include irradiating the light λ2 having the second wavelength, and then analyzing an image due to difference in fluorescence properties at the first wavelength range between the second dielectric layer 102 and the second redistribution patterns 132 (S20).

As shown in FIG. 3F, the light λ2 having the second wavelength may be irradiated to the second redistribution patterns 132 and the second dielectric layer 102. The second wavelength may correspond to an excitation wavelength of the second dielectric layer 102.

As shown in FIG. 3G, the second dielectric layer 102 may absorb the light λ2 having the second wavelength, and may emit the light λ1′ having the first wavelength range. The light λ1′ having the first wavelength range may be fluorescently emitted light. The second redistribution patterns 132 may have no fluorescence properties. Durability and reliability of the second redistribution patterns 132 may be evaluated based on analyzed results of the image due to difference in fluorescence properties. Because the second dielectric layer 102 has a fluorescence intensity equal to or greater than about 4×10³ at the first wavelength range, the fluorescence inspection may increase in reliability.

For example, the second dielectric layer 102 may have an integral intensity equal to or greater than about 40 at the absorbance of the first wavelength range. In this case, the fluorescence inspection may increase in reliability.

Referring to FIG. 3H, a third dielectric layer 103 may be formed on and may cover the second dielectric layer 102 and the second redistribution patterns 132. The third dielectric layer 103 may be formed by substantially the same method as that used for forming the first dielectric layer 101 of FIG. 3A. The third dielectric layer 103 may be cured.

First redistribution pads 150 may be formed in the third dielectric layer 103 and on a top surface of the third dielectric layer 103. The first redistribution pads 150 may be coupled to the second redistribution pattern 132. The first redistribution pads 150 may be formed by a deposition process and an electroplating process. The first redistribution pads 150 may expose at least a portion of the top surface of the third dielectric layer 103.

An inspection process may be performed on the first redistribution pads 150. The inspection process of the first redistribution pads 150 may include an absorbance inspection. According to some example embodiments, the light λ1 having the first wavelength range may be irradiated to the first redistribution pads 150 and the third dielectric layer 103. The first redistribution pads 150 may reflect the light λ1 having the first wavelength range. The third dielectric layer 103 may absorb the light λ1 having the first wavelength range. An analysis may be performed of an image due to difference in absorbance at the first wavelength range (S10). It may be evaluated whether the first redistribution pads 150 are defective based on analyzed results.

The third dielectric layer 103 may have an absorbance equal to or greater than about 0.04 at the light λ1 having the first wavelength range, and an integral intensity equal to or greater than about 13 at the first wavelength range, and thus the occurrence of noise may be reduced or prevented. For example, the third dielectric layer 103 may have an absorbance equal to or greater than about 0.5 at the light λ1 having the first wavelength range, and an integral intensity equal to or greater than about 40 at the first wavelength range. In this case, it may be possible to increase reliability and accuracy of results of analyzing the image due to difference in absorbance.

Referring to FIG. 3I, the inspection process of the first redistribution pads 150 may include a fluorescence inspection. The fluorescence inspection may be performed on the third dielectric layer 103. The light λ2 having the second wavelength may be irradiated to the first redistribution pads 150 and the third dielectric layer 103. The first redistribution pads 150 may have no fluorescence properties.

Referring FIG. 3J, the third dielectric layer 103 may absorb the light λ2 having the second wavelength, and may emit the light λ1′ having the first wavelength range. The light λ1′ having the first wavelength range may be fluorescently emitted light. Because the first redistribution pads 150 have no fluorescence properties, no light may be emitted from the first redistribution pads 150. An analysis may be performed of an image due to difference in fluorescence properties. The analysis of the image due to the fluorescence difference may include analyzing contrast due to difference in fluorescence properties between the third dielectric layer 103 and the first redistribution pads 150. Durability and reliability of the first redistribution pads 150 may be evaluated based on analyzed results. Because the third dielectric layer 103 has a fluorescence intensity equal to or greater than about 4×10³ at the first wavelength range, the fluorescence inspection may increase in reliability.

For example, the third dielectric layer 103 may have an integral intensity equal to or greater than about 40 at the absorbance of the first wavelength range. In this case, the fluorescence inspection may increase in reliability.

The fluorescence inspection of the third dielectric layer 103 may be performed by substantially the same method as that used for performing the fluorescence inspection discussed in the example of FIG. 2, 3C, or 3F.

Referring to FIG. 3K, a semiconductor chip 200 may be mounted on a top surface of the first redistribution substrate 100. The mounting of the semiconductor chip 200 may include forming bumps 250 between the first redistribution substrate 100 and the semiconductor chip 200. The bumps 250 may be coupled to the first redistribution pads 150 and to chip pads 230 of the semiconductor chip 200. An underfill layer 410 may further be formed between the first redistribution substrate 100 and the semiconductor chip 200. A molding layer 400 may be formed on the top surface of the first redistribution substrate 100 to cover the semiconductor chip 200.

Referring to FIG. 3L, the carrier substrate 900 may be removed to expose a bottom surface of the first redistribution substrate 100. For example, there may be exposed a bottom surface 101b of the first dielectric layer 101 and bottom surfaces of the under-bump patterns 120.

Referring back to FIG. 1A, solder balls 500 may be correspondingly formed on the bottom surfaces of the under-bump patterns 120, thereby being coupled to the under-bump patterns 120. Through the processes discussed above, a semiconductor package 10 may be eventually fabricated.

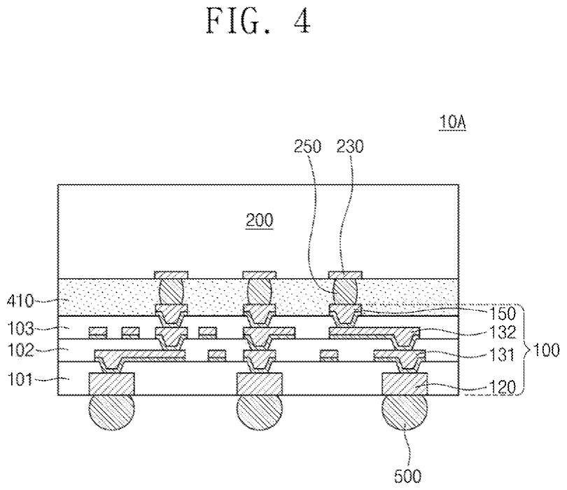

FIG. 4 illustrates a cross-sectional view showing a semiconductor package according to some example embodiments.

Referring to FIG. 4, a semiconductor package 10A may include a first redistribution substrate 100, a semiconductor chip 200, solder balls 500, bumps 250, and an underfill layer 410. The semiconductor package 10A may not include the molding layer 400 discussed in FIG. 1A. The semiconductor chip 200 may have a width substantially the same as that of the first redistribution substrate 100 and that of the underfill layer 410. The semiconductor chip 200 may have sidewalls vertically aligned with those of the first redistribution substrate 100. The semiconductor package 10A may be a fan-in semiconductor package.

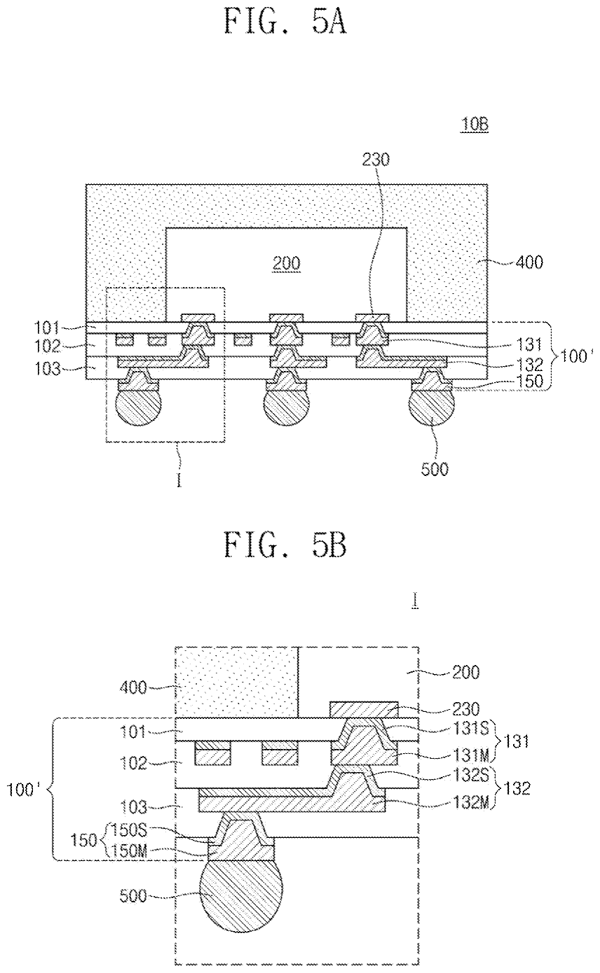

FIG. 5A illustrates a cross-sectional view showing a semiconductor package according to some example embodiments. FIG. 5B illustrates an enlarged view showing section I of FIG. 5A.

Referring to FIGS. 5A and 5B, a semiconductor package 10B may include a first redistribution substrate 100′, solder balls 500, a semiconductor chip 200, and a molding layer 400. The semiconductor package 10B may not include any of the bumps 250 and the underfill layer 410 that are discussed in FIG. 1A.

The first redistribution substrate 100′ may include first, second, and third dielectric layers 101, 102, and 103, first redistribution patterns 131, second redistribution patterns 132, and first redistribution pads 150. The first redistribution substrate 100′ may not include the under-bump patterns 120 discussed in FIGS. 1A and 1B. The first redistribution substrate 100′ may be in direct contact with the semiconductor chip 200 and the molding layer 400. For example, the first dielectric layer 101 may be in direct contact with a bottom surface of the semiconductor chip 200 and with a bottom surface of the molding layer 400. The first redistribution patterns 131 may be provided in the first dielectric layer 101 and on a bottom surface of the first dielectric layer 101. A first via part of each of the first redistribution patterns 131 may vertically overlap a corresponding chip pad 230. As shown in FIG. 5B, each of the first redistribution patterns 131 may include a first seed pattern 131S and a first metal pattern 131M. The first seed pattern 131S may be disposed on a top surface of the first metal pattern 131M. The first seed pattern 131S may be directly coupled to the chip pad 230. After the first redistribution patterns 131 are formed, the inspection process of FIG. 2 may be performed. For example, there may be performed an analysis of an image due to difference in absorbance at a first wavelength range between the first redistribution patterns 131 and the first dielectric layer 101 (see S10 of FIG. 2), and may also be performed an irradiation of light having a second wavelength to execute an analysis of an image due to difference in fluorescence properties at the first wavelength range between the first redistribution patterns 131 and the first dielectric layer 101 (se S20 of FIG. 2). The inspection process may be performed by the same method as that discussed in the inspection process of the first redistribution patterns 131 shown in FIGS. 3B to 3D.

The second dielectric layer 102 may be provided on the bottom surface of the first dielectric layer 101. The second redistribution patterns 132 may be provided in the second dielectric layer 102 and on a bottom surface of the second dielectric layer 102. As shown in FIG. 5B, each of the second redistribution patterns 132 may include a second seed pattern 132S and a second metal pattern 132M. The second seed pattern 132S may be disposed on a top surface of the second metal pattern 132M. The second redistribution patterns 132 may be correspondingly coupled to the first redistribution patterns 131. After the formation of the second dielectric layer 102 and the second redistribution patterns 132, the inspection process of FIG. 2 may be performed.

The third dielectric layer 103 may be provided on a bottom surface of the second dielectric layer 102. First redistribution pads 150 may be provided in the third dielectric layer 103 and on a bottom surface of the third dielectric layer 103. As shown in FIG. 5B, each of the first redistribution pads 150 may include a seed pad 150S and a metal pad 150M. The seed pad 150S may be disposed on a top surface of the metal pad 150M. The first redistribution pads 150 may be correspondingly coupled to the second redistribution patterns 132. After the formation of the third dielectric layer 103 and the first redistribution pads 150, the inspection process of FIG. 2 may be performed.

The first redistribution pads 150 may be solder pads. For example, solder balls 500 may be correspondingly disposed on bottom surfaces of the first redistribution pads 150. Although not shown, a protective dielectric layer may further be provided on the bottom surface of the third dielectric layer 103 to cover sidewalls of the first redistribution pads 150. The protective dielectric layer may not cover the solder balls 500.

The semiconductor package 10B may be fabricated by a chip-first process, for example.

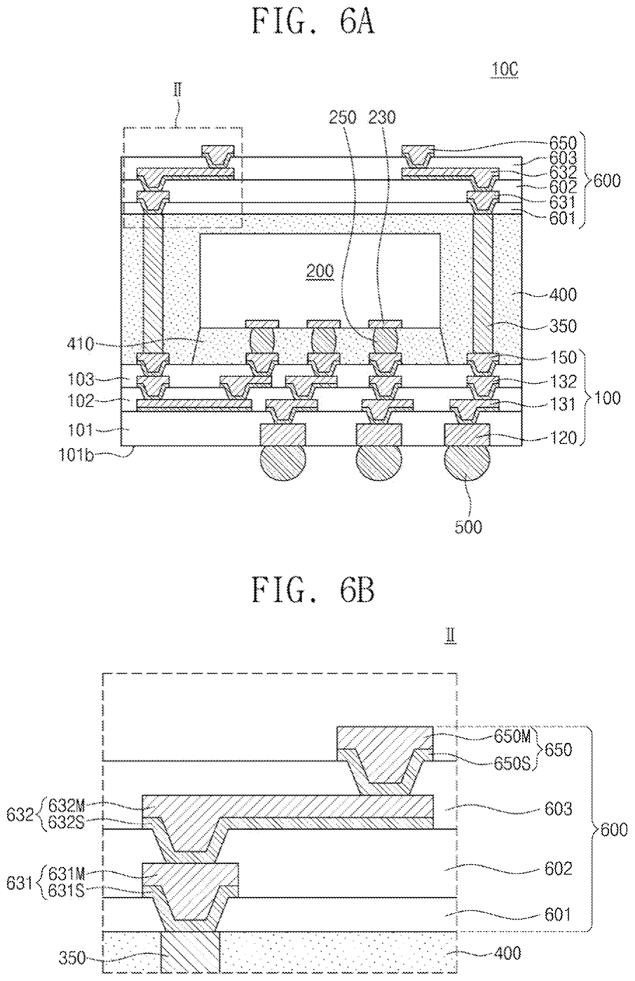

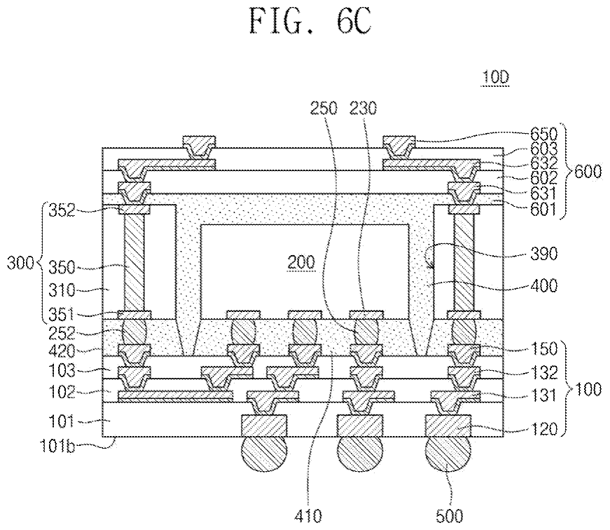

FIG. 6A illustrates a cross-sectional view showing a semiconductor package according to some example embodiments. FIG. 6B illustrates an enlarged cross-sectional view showing section II of FIG. 6A.

Referring to FIGS. 6A and 6B, a semiconductor package 10C may include a first redistribution substrate 100, solder balls 500, a semiconductor chip 200, conductive structures 350, and a molding layer 400. The semiconductor package 10 may further include at least one selected from bumps 250, an underfill layer 410, and a second redistribution substrate 600. The semiconductor package 10C may be a lower package. The first redistribution substrate 100 may be substantially the same as the first redistribution substrate 100 discussed in FIG. 1A.

The conductive structures 350 may be disposed on a top surface of the first redistribution substrate 100. For example, the conductive structures 350 may be disposed on the top surface at an edge region of the first redistribution substrate 100. The conductive structures 350 may be laterally spaced apart from the semiconductor chip 200. The conductive structures 350 may be spaced apart from each other. The conductive structures 350 may be electrically connected through the first redistribution substrate 100 to the semiconductor chip 200 or the solder balls 500. The conductive structures 350 may be metal pillars. For example, the conductive structures 350 may include metal, such as copper.

The molding layer 400 may be disposed on the top surface of the first redistribution substrate 100 to cover the semiconductor chip 200 and lateral surfaces of the conductive structures 350. The molding layer 400 may not cover top surfaces of the conductive structures 350. The molding layer 400 may have a lateral surface aligned with that of the first redistribution substrate 100. The molding layer 400 may include a dielectric polymer, such as an epoxy-based polymer.

The second redistribution substrate 600 may be provided on a top surface of the molding layer 400 and top surfaces of the conductive structures 350. The second redistribution substrate 600 may include upper dielectric layers, first upper redistribution patterns 631, second upper redistribution patterns 632, and second redistribution pads 650. The upper dielectric layers may include a first upper dielectric layer 601, a second upper dielectric layer 602, and a third upper dielectric layer 603 that are sequentially stacked on the molding layer 400. The first, second, and third upper dielectric layers 601, 602, and 603 may be organic dielectric layers.

Each of the first, second, and third upper dielectric layers 601, 602, and 603 may absorb light having a first wavelength range. For example, each of the first, second, and third upper dielectric layers 601, 602, and 603 may have an absorbance equal to or greater than about 0.04 for light having the first wavelength range. The absorbance may be a maximum absorbance. Each of the first, second, and third upper dielectric layers 601, 602, and 603 may have an integral intensity equal to or greater than about 13 at the absorbance of the first wavelength range. The integral intensity may be a definite integral of an absorbance function at the first wavelength range. The integral intensity may be an area of an absorbance function at the first wavelength range. The first wavelength may be the same as that discussed above in FIG. 1A.

The first, second, and third upper dielectric layers 601, 602, and 603 may have fluorescence properties with respect to incident light having a second wavelength. For example, when light having the second wavelength is irradiated, light having the first wavelength range may be emitted from the first, second, and third upper dielectric layers 601, 602, and 603. For example, the second wavelength may be less than the first wavelength range. The second wavelength may be, e.g., about 400 nm to about 410 nm. For another example, the second wavelength may be about 475 nm to about 485 nm. Each of the first, second, and third upper dielectric layers 601, 602, and 603 may have a fluorescence intensity equal to or greater than about 4×10³ at an emission wavelength of the first wavelength range.

The first, second, and third upper dielectric layers 601, 602, and 603 may satisfy at least one selected from the first absorbance condition and the first fluorescence condition that are discussed above. The first absorbance condition may include an absorbance equal to or greater than about 0.5 with respect to light having the first wavelength range. The first absorbance condition may include an integral intensity equal to or greater than about 40 at the absorbance of the first wavelength range. The first fluorescence condition may include having a fluorescence intensity equal to or greater than about 1.0×10⁶ at an emission wavelength of the first wavelength range.

Each of the first, second, and third upper dielectric layers 601, 602, and 603 may include a photo-imageable dielectric composition. The photo-imageable dielectric composition may include the base resin, the cross-linking agent, the elastomer, the photo active compound, and the photosensitizer, which are discussed in the example of the first, second, and third dielectric layers 101, 102, and 103 of FIG. 1A.

The first, second, and third upper dielectric layers 601, 602, and 603 may include the same photo-imageable dielectric composition. An instinct interface may be provided between the first upper dielectric layer 601 and the second upper dielectric layer 602. An instinct interface may be provided between the second upper dielectric layer 602 and the third upper dielectric layer 603. The first, second, and third upper dielectric layers 601, 602, and 603 may be in a cured state. Alternatively, the first, second, and third upper dielectric layers 601, 602, and 603 may include an adhesive dielectric film such as an Ajinomoto build-up film. The number of the first, second, and third upper dielectric layers 601, 602, and 603 may be variously changed.

Each of the first, second, and third upper dielectric layers 601, 602, and 603 may have a thickness of about 3 μm to about 15 μm. For example, each of the first, second, and third upper dielectric layers 601, 602, and 603 may have a thickness of about 3 μm to about 8 μm.

The first upper redistribution patterns 631 may be provided in and on the first upper dielectric layer 601. The first upper redistribution patterns 631 may be provided on and electrically connected to the conductive structures 350. The first upper redistribution patterns 631 may be laterally spaced apart and electrically separated from each other. After the formation of the first upper dielectric layer 601 and the first upper redistribution patterns 631, the inspection process of FIG. 2 may be performed.

The second upper dielectric layer 602 may be disposed on the first upper dielectric layer 601 and the first upper redistribution patterns 631, thereby covering the first upper redistribution patterns 631. The second upper redistribution patterns 632 may be disposed on and electrically connected to the first upper redistribution patterns 631. The second upper redistribution patterns 632 may be provided in and on the second upper dielectric layer 602. After the formation of the second upper dielectric layer 602 and the second upper redistribution patterns 632, the inspection process of FIG. 2 may be performed.

The third upper dielectric layer 603 may be provided on the second upper dielectric layer 602 and top surfaces of the second upper redistribution patterns 632, thereby covering the top surfaces of the second upper redistribution patterns 632. Second redistribution pads 650 may be provided in and on the third upper dielectric layer 603. After the formation of the third upper dielectric layer 603 and the second redistribution pads 650, an inspection process of FIG. 2 may be performed on the third upper dielectric layer 603.

The second redistribution pads 650 may be disposed on and coupled to the second upper redistribution patterns 632. The second redistribution pads 650 may be coupled through the second upper redistribution patterns 632 to the conductive structures 350. At least one of the second redistribution pads 650 may not be vertically aligned with the conductive structure 350 electrically connected thereto. Accordingly, it may be possible to freely design an arrangement of the second redistribution pads 650.

The following will describe in detail the first upper redistribution patterns 631, the second upper redistribution patterns 632, and the second redistribution pads 650.

Referring to FIG. 6B, each of the first upper redistribution patterns 631 may include a first upper seed pattern 631S and a first upper metal pattern 631M. The first upper metal pattern 631M may include a first via and a first wire. The first via may be provided in the first upper dielectric layer 601. The first wire may be provided on the first via, and the first wire and the first via may be connected to each other without an interface therebetween. The first wire may extend onto a top surface of the first upper dielectric layer 601. The first upper metal pattern 631M may include metal, such as copper. The first upper seed pattern 631S may be interposed between a corresponding conductive structure 350 and the first upper metal pattern 631M and between the first upper dielectric layer 601 and the first upper metal pattern 631M. The first upper seed pattern 631S may include a conductive seed material. The first upper seed pattern 631S may be a barrier layer.

Each of the second upper redistribution patterns 632 may include a second upper seed pattern 632S and a second upper metal pattern 632M. The second upper metal pattern 632M may include a second via and a second wire. The second via may be provided in the second upper dielectric layer 602. The second wire may be provided on the second via, and the second wire and the second via may be connected to each other without an interface therebetween. The second wire may extend onto a top surface of the second upper dielectric layer 602. The second upper metal pattern 632M may include metal, such as copper. The second upper seed pattern 632S may be interposed between a corresponding first upper redistribution pattern 631 and the second upper metal pattern 632M and between the second upper dielectric layer 602 and the second upper metal pattern 632M. The second upper seed pattern 632S may include a different material from that of the second upper metal pattern 632M. The second upper seed pattern 632S may include a conductive seed material. The second upper seed pattern 632S may serve as a barrier layer. The phrase “electrically connected to the second redistribution substrate 600” may include the meaning that “coupled to at least one selected to the first and second upper redistribution patterns 631 and 632.”

Each of the second redistribution pads 650 may include a seed pad pattern 650S and a metal pad pattern 650M. The metal pad pattern 650M may have a lower portion that is provided in the second upper dielectric layer 602. The lower portion of the metal pad pattern 650M may extend onto the top surface of the second upper dielectric layer 602. The metal pad pattern 650M may include metal, such as copper. The seed pad pattern 650S may be interposed between a corresponding second upper redistribution pattern 632 and the metal pad pattern 650M and between the third upper dielectric layer 603 and the metal pad pattern 650M. The seed pad pattern 650S may include a different material from that of the metal pad pattern 650M. The seed pad pattern 650S may include a conductive seed material. The seed pad pattern 650S may serve as a barrier layer.

Differently from that shown, third redistribution patterns may further be interposed between the second upper redistribution patterns 632 and the second redistribution pads 650. Although not shown, the second upper redistribution patterns 632 may be omitted, and the second redistribution pads 650 may be directly coupled to the first upper redistribution patterns 631.

Alternatively, the semiconductor package 10C may not include the second redistribution substrate 600.

FIG. 6C illustrates a cross-sectional view showing a semiconductor package according to some example embodiments.

Referring to FIG. 6C, a semiconductor package 10D may include a first redistribution substrate 100, solder balls 500, a semiconductor chip 200, a connection substrate 300, and a molding layer 400. The semiconductor package 10D may further include at least one selected from a second redistribution substrate 600, bumps 250, an underfill layer 410, connection bumps 252, and an underfill pattern 420. The semiconductor package 10D may be a lower package.

The connection substrate 300 may be disposed on the first redistribution substrate 100. The connection substrate 300 may have a substrate hole 390 that penetrates therethrough. For example, the connection substrate 300 may be manufactured by forming the substrate hole 390 that penetrates top and bottom surfaces of a printed circuit board. When viewed in plan, the substrate hole 390 may be formed on a central portion of the connection substrate 300. The semiconductor chip 200 may be disposed in the substrate hole 390 of the connection substrate 300. The semiconductor chip 200 may be disposed spaced apart from an inner lateral surface of the connection substrate 300.

The connection substrate 300 may include a base layer 310, first pads 351, conductive structures 350, and second pads 352. The base layer 310 may include a dielectric material. For example, the base layer 310 may include a carbon-based material, a ceramic, or a polymer. The substrate hole 390 may penetrate the base layer 310. The conductive structures 350 may be provided in the base layer 310. The first pads 351 may be provided on bottom surfaces of the conductive structures 350. The first pads 351 may be exposed on a bottom surface of the connection substrate 300. The second pads 352 may be disposed on top surfaces of the conductive structures 350. The second pads 352 may be exposed on a top surface of the connection substrate 300. The second pads 352 may be electrically connected through the conductive structures 350 to the first pads 351. The conductive structures 350, the first pads 351, and the second pads 352 may include metal, such as copper, aluminum, tungsten, titanium, tantalum, or an alloy thereof.

The connection bumps 252 may be provided between the first redistribution substrate 100 and the connection substrate 300, thereby being coupled to the first redistribution pads 150 and the first pads 351. The connection bumps 252 may include a solder material.

The underfill pattern 420 may be provided between the first redistribution substrate 100 and the connection substrate 300, thereby encapsulating the connection bump 252. The underfill pattern 420 may include a dielectric polymer discussed in the example of the underfill layer 410.

The molding layer 400 may be provided on the first redistribution substrate 100 and may be interposed between the semiconductor chip 200 and the connection substrate 300. The molding layer 400 may cover a top surface of the semiconductor chip 200 and the top surface of the connection substrate 300. According to some example embodiments, an adhesive dielectric film may be attached to the top surface of the connection substrate 300, the top surface of the semiconductor chip 200, and lateral surfaces of the semiconductor chip 200, thereby forming the molding layer 400. For example, an Ajinomoto build-up film (ABF) may be used as the adhesive dielectric film. Alternatively, the molding layer 400 may include a dielectric polymer, such as an epoxy-based polymer.

The second redistribution substrate 600 may be disposed on the molding layer 400 and the connection substrate 300. The second redistribution substrate 600 may be substantially the same as that discussed in the example of FIGS. 5A and 5B. In contrast, the first upper redistribution patterns 631 may further extend into the molding layer 400 to be coupled to the second pads 352. The first upper dielectric layer 601 may be provided on the first upper redistribution patterns 631 and the molding layer 400.

The second upper redistribution patterns 632 may be provided on the first upper redistribution patterns 631 and the first upper dielectric layer 601. After the formation of the first upper dielectric layer 601 and the second upper redistribution patterns 632, the inspection process of FIG. 2 may be performed.

The second upper dielectric layer 602 may be formed on the second upper redistribution patterns 632 and the first upper dielectric layer 601, and may cover the second upper redistribution patterns 632. The second redistribution pads 650 and the second upper dielectric layer 602 may be formed in and on the second upper dielectric layer 602, and may be coupled to the second upper redistribution patterns 632. After the formation of the second upper dielectric layer 602 and the second redistribution pads 650, the inspection process of FIG. 2 may be performed.

Alternatively, the semiconductor package 10D may not include the second redistribution substrate 600.

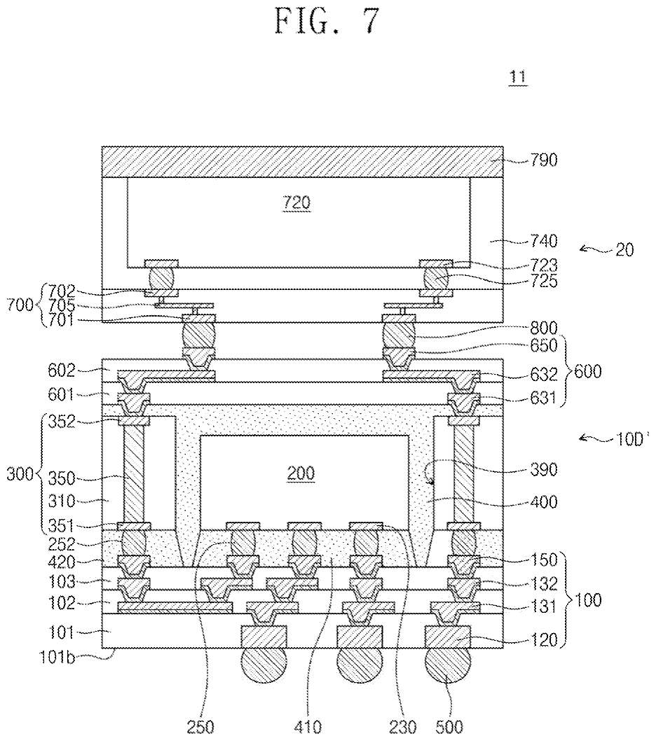

FIG. 7 illustrates a cross-sectional view showing a semiconductor package according to some example embodiments.

Referring to FIG. 7, a semiconductor package 11 may include a lower package 10D′, an upper package 20, and connection solders 800. The lower package 10D′ may be substantially the same as the semiconductor package 10D discussed in the example of FIG. 5C. The lower package 10D′ may include a first redistribution substrate 100, solder balls 500, a semiconductor chip 200, a molding layer 400, a connection substrate 300, and a second redistribution substrate 600. Alternatively, the semiconductor package 10C of FIGS. 5A and 5B may be adopted as the lower package 10D′.

The upper package 20 may include an upper substrate 700, an upper semiconductor chip 720, and an upper molding layer 740. The upper substrate 700 may be disposed on and spaced apart from a top surface of the second redistribution substrate 600. The upper substrate 700 may be a printed circuit board (PCB) or a redistribution layer. The upper substrate 700 may include first metal pads 701 disposed on a bottom surface thereof, and may also include second metal pads 702 disposed on a top surface thereof. The upper substrate 700 may be provided therein with metal lines 705 coupled to the first metal pads 701 and the second metal pads 702.

The connection solders 800 may be interposed between the second redistribution substrate 600 and the upper substrate 700, and may be coupled to the second redistribution pads 650 and the first metal pads 701. The connection solders 800 may include a solder material. Although not shown, the connection solders 800 may further include metal pillar patterns.

The upper semiconductor chip 720 may be mounted on the upper substrate 700. The upper semiconductor chip 720 may be of a different type from the semiconductor chip 200. For example, the upper semiconductor chip 720 may be a memory chip, and the semiconductor chip 200 may be a logic chip. Upper bumps 725 may be provided between the upper substrate 700 and the upper semiconductor chip 720. The upper bumps 725 may be correspondingly coupled to the second metal pads 702 and also coupled to chip pads 723 of the upper semiconductor chip 720. The upper bumps 725 may include solder balls. Although not shown, the upper bumps 725 may further include pillar patterns. The upper semiconductor chip 720 may be coupled to the semiconductor chip 200 or the solder balls 500 through the connection solders 800, the second redistribution substrate 600, and the conductive structures 350.

The upper substrate 700 may be provided thereon with the upper molding layer 740 that covers the upper semiconductor chip 720. The upper molding layer 740 may expose a top surface of the upper semiconductor chip 720. Differently from that shown, the upper molding layer 740 may further cover the top surface of the upper semiconductor chip 720. The upper molding layer 740 may include a dielectric polymer, such as an epoxy-based molding compound.

The upper package 20 may further include a thermal radiation structure 790. The thermal radiation structure 790 may be disposed on the top surface of the upper semiconductor chip 720 and on a top surface of the upper molding layer 740. The thermal radiation structure 790 may further extend onto a lateral surface of the upper molding layer 740. The thermal radiation structure 790 may include a heat sink, a heat slug, or a thermal interface material (TIM) layer. The thermal radiation structure 790 may include, e.g., metal.

Example embodiments may be combined with each other. For example, the first redistribution substrate 100′ of FIG. 5 may be included in the semiconductor package 10A of FIG. 4, the semiconductor package 10C of FIGS. 6A and 6B, the semiconductor package 10D of FIG. 6C, and the semiconductor package 11 of FIG. 7. In this case, the bumps 250 and the underfill layer 410 may be omitted, and the first redistribution substrate 100′ may be in contact with the semiconductor chip 200 and the molding layer 400.

The following Examples are provided in order to set forth particular details of one or more example embodiments. However, it will be understood that the embodiments described herein are not limited to the particular details described in the Examples.

With reference to Experimental Examples, the following will describe the fabrication and property evaluation results of a dielectric layer.

### FABRICATION OF EXPERIMENTAL EXAMPLES

### 1. Experimental Example 1

A base resin, a cross-linking agent, an elastomer, and a photo active compound were mixed to manufacture a photo-imageable dielectric composition. The base resin included one of polyamide resins, polybenzoxazole resins, phenolic resins, and hydroxystyrene resins. The cross-linking agent included one of hexamethylol melamine, hexabutanol melamine, 1,4 bis(methoxymethyl)benzene, 1,3-bis(methoxymethyl)benzene, 4,4′ bis(methoxymethyl)biphenyl, 3,4′-bis(methoxymethyl)biphenyl, 3,3′ bis(methoxymethyl)biphenyl, 2,6-naphthalene naphthalenedicarboxylic acid methyl, 4,4′ methylenebis(2,6-methoxymethyl phenol), ethylene glycol diglycidyl ether, bisphenol A diglycidyl ether, isocyanuric acid triglycidyl, bisphenol A epoxy resins, bisphenol F epoxy resins, naphthalene epoxy resins, biphenyl epoxy resins, and phenol novolac epoxy resins. The elastomer included one of phenolic compounds, melamine compounds, imide compounds, and any derivative thereof. The photo active compound included a diazonaphthoquinone compound.

The photo-imageable dielectric composition was coated to a thickness of about 3 μm to about 15 μm to form preliminary dielectric layers. The preliminary dielectric layers were annealed during about 30 seconds to about 30 minutes at a temperature of about 90° C. to 130° C. The preliminary dielectric layers were cured for about 30 minutes to about 10 hours at a temperature of about 150° C. to about 350° C. Thereby, a dielectric layer of Experimental Example 1 was manufactured.

### 2. Experimental Example 2

A dielectric layer was manufactured by the same method as that used in Experimental Example 1. In this case, among hexamethylol melamine, hexabutanol melamine, 1,4 bis(methoxymethyl)benzene, 1,3-bis(methoxymethyl)benzene, 4,4′ bis(methoxymethyl)biphenyl, 3,4′-bis(methoxymethyl)biphenyl, 3,3′ bis(methoxymethyl)biphenyl, 2,6-naphthalene naphthalenedicarboxylic acid methyl, 4,4′ methylenebis(2,6-methoxymethyl phenol), ethylene glycol diglycidyl ether, bisphenol A diglycidyl ether, isocyanuric acid triglycidyl, bisphenol A epoxy resins, bisphenol F epoxy resins, naphthalene epoxy resins, biphenyl epoxy resins, and phenol novolac epoxy resins, the cross-linking agent included one different from the material selected as the cross-linking agent of Experimental Example 1. In addition, among phenolic compounds, melamine compounds, imide compounds, and any derivative thereof, the elastomer included one different from the material selected as the elastomer of Experimental Example 2. Thereby, a photo-imageable dielectric composition was manufactured.

### 3. Experimental Example 3

A dielectric layer was manufactured by the same method used in Experimental Example 2. In contrast, among phenolic compounds, melamine compounds, imide compounds, and any derivative thereof, one different from the material selected in Experimental Examples 1 and 2 was used to manufacture a photo-imageable dielectric composition.

### 4. Experimental Example 4

A dielectric layer was manufactured by the same method used in Experimental Example 2. A melamine derivative was further added to a photo-imageable compound.

### 5. Experimental Example 5

A dielectric layer was manufactured by the same method used in Experimental Example 4. A photo-imageable dielectric composition was added with a melamine derivative of a different type from that used in Experimental Example 4.

### EVALUATION OF EXPERIMENTAL EXAMPLES

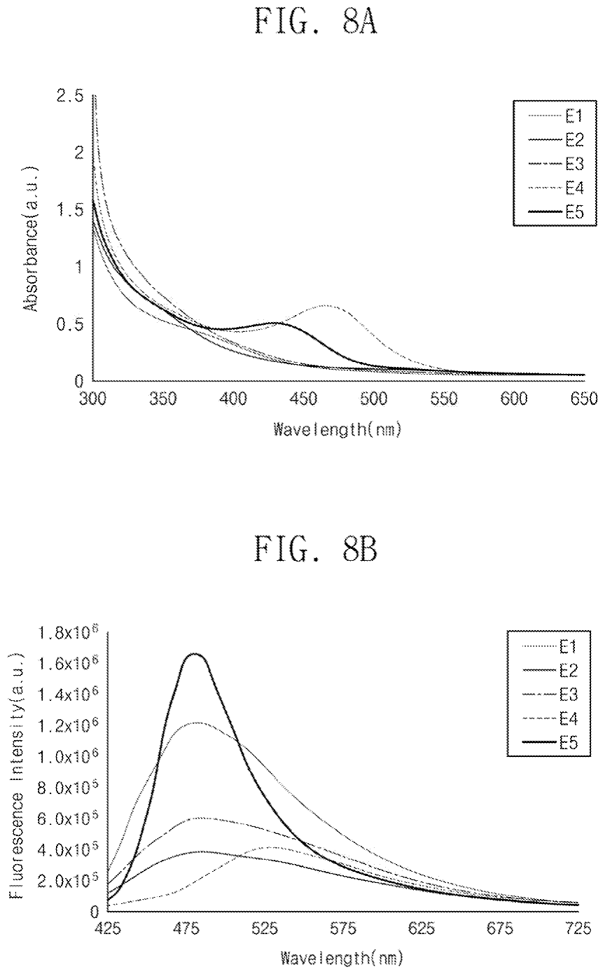

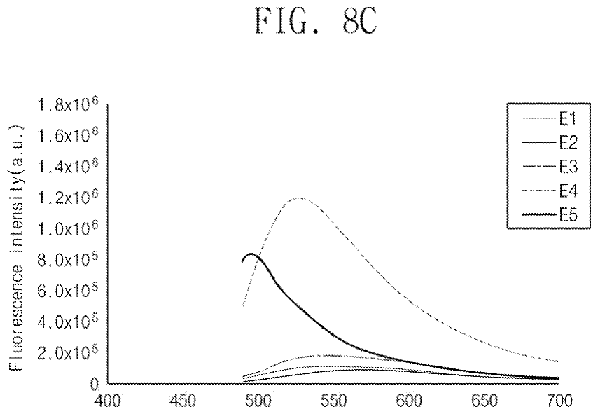

FIG. 8A illustrates a graph showing an evaluation result of absorbance of Experimental Examples 1 to 5. FIG. 8B illustrates a graph showing an evaluation result of fluorescence intensity of Experimental Examples 1 to 5 when irradiating light whose wavelength is about 405 nm. FIG. 8C illustrates a graph showing an evaluation result of fluorescence intensity of Experimental Examples 1 to 5 when irradiating light whose wavelength is about 480 nm.

In FIGS. 8A, 8B, and 8C, the following labels are used: Experimental Example 1 (E1), Experimental Example 2 (E2), Experimental Example 3 (E3), Experimental Example 4 (E4), and Experimental Example 5 (E5).

Referring to FIG. 8A, absorbance was measured by irradiating the dielectric layers of Experimental Examples 1 to 5 with light ranging from about 450 nm to about 650 nm. Data therefor is set forth in Table 1.

Referring to FIG. 8B, the dielectric layers of Experimental Examples 1 to 5 were irradiated with light whose wavelength was about 405 nm, and then a fluorescence intensity was measured at the wavelength range of about 450 nm to about 650 nm. Data therefor is set forth in Table 1.

Referring to FIG. 8C, the dielectric layers of Experimental Examples 1 to 5 were irradiated with light whose wavelength was about 480 nm, and then a fluorescence intensity was measured at the wavelength range of about 480 nm to about 650 nm.

The fluorescence intensities and the absorbance were measured by using the same apparatus.

Table 1 below lists an evaluation result of the absorbance and the fluorescence intensity measured in Experimental Examples 1 to 5 (in Table 1, a.u. means arbitrary unit).

TABLE 1

| | Exp. Ex. 1 | Exp. Ex. 2 | Exp. Ex. 3 | Exp. Ex. 4 | Exp. Ex. 5 |
|---|---|---|---|---|---|
| Maximum | 0.14 | 0.14 | 0.15 | 0.66 | 0.43 |
| Absorbance | | | | | |
| (a.u.) | | | | | |
| Absorbance | 13.84 | 16.81 | 15.35 | 47.45 | 23.97 |
| Integral Area | | | | | |
| (a.u.) | | | | | |
| Fluorescence | 1.2 | 0.4 | 0.6 | 0.4 | 1.6 |
| Intensity | | | | | |
| (×10⁶) (a.u.) | | | | | |

FIG. 8A illustrates a graph showing an evaluation result of absorbance of Experimental Examples 1 to 5.

Referring to FIG. 8A and Table 1, the dielectric layers of Experimental Example 1 (E1), Experimental Example 2 (E2), Experimental Example 3 (E3), Experimental Example 4 (E4), and Experimental Example 5 (E5) may each exhibit a maximum absorbance equal to or greater than about 0.04 with respect to light ranging from about 450 nm to about 650 nm. The dielectric layers of Experimental Examples 1 to 5 (E1 to E5) may each have an integral area greater than about 13 of absorbance at a wavelength range of about 450 nm to about 650 nm.

Also, the dielectric layer of Experimental Example 4 (E4) may exhibit a maximum absorbance equal to or greater than about 0.5 with respect to light ranging from about 450 nm to about 650 nm. The dielectric layer of Experimental Example 4 (E4) may have an integral area greater than about 40 of absorbance at a wavelength of about 450 nm to about 650 nm.

FIG. 8B illustrates a graph showing an evaluation result of fluorescence intensity of Experimental Examples 1 to 5 when irradiating light whose wavelength is about 405 nm.

Referring to FIG. 8B and Table 1, the dielectric layers of Experimental Example 1 (E1), Experimental Example 2 (E2), Experimental Example 3 (E3), Experimental Example 4 (E4), and Experimental Example 5 (E5) may each have a fluorescence intensity equal to or greater than about 4×10³ at a wavelength range of about 450 nm to about 650 nm. Also, the dielectric layers of Experimental Examples 1 and 2 (E1 and E2) may each have a fluorescence intensity equal to or greater than about 1.0×10⁶ at a wavelength range of 450 nm to about 650 nm.

FIG. 8C illustrates a graph showing an evaluation result of fluorescence intensity of Experimental Examples 1 to 5 when irradiating light having a wavelength of about 480 nm.

Referring to FIG. 8C, when irradiating light whose wavelength is about 480 nm, the dielectric layers of Experimental Example 1 (E1), Experimental Example 2 (E2), Experimental Example 3 (E3), Experimental Example 4 (E4), and Experimental Example 5 (E5) may each have a fluorescence intensity equal to or greater than about 4×10³ at a wavelength range of about 450 nm to about 650 nm. Also, the dielectric layer of Experimental Example 4 (E4) may have a fluorescence intensity equal to or greater than about 1.0×10⁶ at a wavelength range of 450 nm to about 650 nm.

According to embodiments, an inspection of a redistribution substrate may include an absorbance inspection and a fluorescence inspection. A dielectric layer may have a relatively high absorbance with respect to visible light having a first wavelength range. Therefore, it may be possible to prevent the occurrence of noise caused by redistribution patterns on a bottom surface of the dielectric layer. The absorbance inspection may evaluate whether defects are present in redistribution patterns on a top surface of the dielectric layer.

The fluorescence inspection may evaluate durability and reliability of the redistribution patterns on the top surface of the dielectric layer. Because the dielectric layer has a high fluorescence intensity, the fluorescence intensity may increase reliability. The fluorescence inspection and the absorbance inspection may be performed at the same first wavelength range, and an inspection process may be simplified.

As described above, embodiments may provide a semiconductor package having enhanced reliability and durability. Embodiments may provide a method of fabricating a semiconductor package, which method is capable of increasing process yield.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

1. A semiconductor package, comprising:
a redistribution substrate that includes an organic dielectric layer and a metal pattern in the organic dielectric layer; and
a semiconductor chip on the redistribution substrate,
wherein the organic dielectric layer has:
a maximum absorbance equal to or greater than about 0.04 a.u. at a first wavelength range; and
a fluorescence intensity equal to or greater than about 4×10³ a.u. at the first wavelength range,
wherein the first wavelength range is about 450 nm to about 650 nm.

2. The semiconductor package as claimed in claim 1, wherein the organic dielectric layer has an integral intensity equal to or greater than about 13 a.u. at an absorbance of the first wavelength range.

3. The semiconductor package as claimed in claim 1, wherein the fluorescence intensity of the organic dielectric layer is equal to or greater than about 1.0×10⁶ a.u.

4. The semiconductor package as claimed in claim 1, wherein an absorbance of the organic dielectric layer is equal to or greater than about 0.5 a.u.

5. The semiconductor package as claimed in claim 1, wherein the organic dielectric layer has an integral intensity equal to or greater than about 40 a.u. at an absorbance of the first wavelength range.

6. The semiconductor package as claimed in claim 1, wherein the fluorescence intensity is a maximum value of the fluorescence intensity at the first wavelength range with respect to an excitation wavelength of a second wavelength.

7. The semiconductor package as claimed in claim 6, wherein the second wavelength is less than the first wavelength range.

8. The semiconductor package as claimed in claim 6, wherein the second wavelength is about 400 nm to about 410 nm.

9. The semiconductor package as claimed in claim 1, wherein the organic dielectric layer includes a base resin, a cross-linking agent, an elastomer, and a photo active compound.

10. The semiconductor package as claimed in claim 1, further comprising a molding layer on a top surface of the redistribution substrate, the molding layer covering a sidewall of the semiconductor chip,
wherein the organic dielectric layer extends onto a bottom surface of the molding layer.

11. The semiconductor package as claimed in claim 10, further comprising a conductive structure on the redistribution substrate and laterally spaced apart from the semiconductor chip,
wherein the molding layer further covers sidewalls of the conductive structures.

12. The semiconductor package as claimed in claim 11, further comprising an upper redistribution substrate on the molding layer and the conductive structures, the upper redistribution substrate being electrically connected to the conductive structures.

13. The semiconductor package as claimed in claim 1, further comprising a connection substrate on the redistribution substrate, the connection substrate having a hole that penetrates the connection substrate,
wherein the semiconductor chip is in the hole of the connection substrate.

14. A semiconductor package, comprising:
a redistribution substrate that includes a dielectric layer and a metal pattern in the dielectric layer;
a plurality of solder balls on a bottom surface of the redistribution substrate; and
a semiconductor chip on a top surface of the redistribution substrate,
wherein the dielectric layer has:
a definite integral value equal to or greater than about 13 a.u. of an absorbance function at a first wavelength range; and
a fluorescence intensity equal to or greater than about 4×10³ a.u. at the first wavelength range,
wherein the dielectric layer satisfies at least one selected from a first fluorescence condition and a first absorbance condition,
wherein the first fluorescence condition includes that the fluorescence intensity is equal to or greater than about 1.0×10⁶ a.u.,
wherein the first absorbance condition includes that a definite integral value is equal to or greater than about 40 of the absorbance function at the first wavelength range, and
wherein the first wavelength range is about 450 nm to about 650 nm.

15. The semiconductor package as claimed in claim 14, wherein the fluorescence intensity is a maximum value of the fluorescence intensity at the first wavelength range with respect to an excitation wavelength of a second wavelength, and
wherein the second wavelength is about 400 nm to about 410 nm.

16. The semiconductor package as claimed in claim 14, wherein the fluorescence intensity is a maximum value of the fluorescence intensity at the first wavelength range with respect to an excitation wavelength of a second wavelength, and
wherein the second wavelength is about 475 nm to about 485 nm.

17. The semiconductor package as claimed in claim 14, wherein the dielectric layer has a maximum absorbance equal to or greater than about 0.5 a.u. at the first wavelength range.

18. A semiconductor package, comprising:
a redistribution substrate that includes a dielectric layer and a redistribution pattern in the dielectric layer;
a plurality of solder balls on a bottom surface of the redistribution substrate;
a semiconductor chip on a top surface of the redistribution substrate; and
a molding layer on the top surface of the redistribution substrate, the molding layer covering the semiconductor chip,
wherein the redistribution pattern includes a seed pattern and a metal pattern on the seed pattern,
wherein the dielectric layer includes a base resin, a cross-linking agent, an elastomer, a photo active compound, and a photosensitizer,
wherein the dielectric layer has:
a maximum absorbance equal to or greater than about 0.04 a.u. at a first wavelength range;
an integral intensity equal to or greater than about 13 a.u. at the first wavelength range; and
a fluorescence intensity equal to or greater than about 4×10³ a.u. at the first wavelength range,
wherein the dielectric layer satisfies at least one selected from a first fluorescence condition and a first absorbance condition,
wherein the first fluorescence condition includes that the fluorescence intensity is equal to or greater than about 1.0×10⁶ a.u.,
wherein the first absorbance condition includes that the integral intensity is equal to or greater than about 40 a.u., and
wherein the first wavelength range is about 450 nm to about 650 nm.

19. The semiconductor package as claimed in claim 18, wherein:
the base resin includes one or more of polyhydroxystyrene (PHS), polybenzoxazole (PBO), novolac-based materials, polyimide (PI), and benzocyclobutene (BCB),
the cross-linking agent includes one or more of an epoxy functional group and an alkoxy functional group,
the elastomer includes a first aromatic ring compound,
the photo active compound includes one or more of diazonaphthoquinone and diazonaphthoquinone derivatives,
the photosensitizer includes a second aromatic ring compound, and
the second aromatic ring compound is different from the first aromatic ring compound.

20-23. (canceled)
